(19) United States
(12) Patent Application Publication
(10) Pub. No.: US 2011/0043192 A1
(43) Pub. Date: Feb. 24, 2011

(54) COAXIAL-CABLE PROBE STRUCTURE

(76) Inventor: Shih-Ming LIU, Gueishan Township (TW)

Correspondence Address: Muncy, Geissler, Olds & Lowe, PLLC, 4000 Legato Road, Suite 310, FAIRFAX, VA, 22033, US

(21) Appl. No.: 12/546,479

(22) Filed: Aug. 24, 2009

(51) Int. Cl. G01R 1/06

(52) U.S. Cl. 324/149

(57) ABSTRACT

A coaxial-cable probe structure comprises a coaxial cable and a probing element. The coaxial cable is formed by filling and fixing an inner conductor into an outer conductor via a dielectric material. The dielectric material of the coaxial cable and the outer conductor are provided with a cutting surface. The inner conductor protrudes from the cutting surface and forms a terminal end. The coaxial cable is provided with a cutting part and the cutting part is provided with an oblique surface relative to the coaxial cable so as to have the inner conductor, the dielectric material, and the outer conductor exposed from the oblique surface. The oblique surface extends to the terminal end of the inner conductor. The probing element includes a first, a second, and a third probe and each probe has a front and a rear interface. The front interface of the second probe is connected with part of the inner conductor exposed from the oblique surface. The front interfaces of the first and third probes are electrically connected to the outer conductor of the coaxial cable. The rear interface of each probe is used to contact the bonding pad of an element under test.

### TECHNICAL FIELD

The present invention relates to a coaxial-cable probe structure for testing the electric characteristics of integrated circuit or other electric elements at high frequency.

### BACKGROUND

Many kinds of probe assemblies have been developed in order to test integrated circuit or other types of micro-electronic elements. To make a representative probe assembly, a circuit board is used. Elongate imprints of conducting wires are formed on the circuit board to be used as signals and ground wires. Probes are connected respectively to the terminal ends of the signal imprints. Accordingly, the tips of the probes face downward and the probes are arranged to extend radially so as to connect selectively with the pads of the micro-electronic elements under test. However, when above probes are used in a test at high frequency, the impedance at high frequency is difficult to be controlled. Consequently, during the process of signal transmitting, problems like reflection or loss of high-frequency signals may occur. Therefore, conventional probes mentioned above are not suitable to be used to test the circuit characterized with high frequency.

Therefore, following probe structures as shown in FIGS. 4˜6 are continuously developed. FIG. 4 shows the structure of a patent with patent number U.S. Pat. No. 4,871,964. The center conductor “b” of a cable “a” protrudes from a cutting surface “d1” of the dielectric material and the outer conductor. The ground conductors “c” are coupled to a portion of the outer conductor “d” located at or near the first end of cable “a”. However, because parts of signal and ground have different structures, the contact force is non-uniform. Accordingly, the space of signal and ground will be deformed and thus the impedance will not be well controlled because of the non-uniform contact force. Besides, round signal trace is not good for co-planar transmission line since electromagnetic field will be crowed in the edge of round conductor and the loss at high frequency is increased.

FIG. 5 shows the structure of a patent with patent number U.S. Pat. No. 5,506,515. At one end of a cable “e” including inner conductor “g”, outer conductor “h”, and inner dielectric “i” forms a common cutting surface “f1” and a semi-cylinder recess “f” thereon. The recess “f” includes inner conductor “g”, outer conductor “h”, and inner dielectric “i”. The first and second resilient conductor fingers (j, k) are respectively connected to the inner conductor “g” and the outer conductor “h”. Each of the first and second resilient conductor fingers (j, k) includes a self-support cantilever portion (j1, k1). The self-support cantilever portions (j1, k1) extend past the cutting surface “f1” of the cable “e”. However, above structure has following disadvantages. (A) At high frequency, discontinuity of the inner conductor “g” at the cutting surface “f1” of the cable “e” and the discontinuity of the outer conductor “h” at the recess “f” will cause impedance mis-match. (B) The semi-cylinder recess is a 2-D fabrication process of high cost. Besides, it is not easy to control the critical dimension of the recess (for example, the depth thereof). (C) In a coaxial cable, the thickness of outer conductor is usually smaller than the diameter of center conductor. By using separate ground conductors, the connecting area of the second resilient conductor and the coaxial cable outer conductor is smaller than that of the center conductor and the first resilient conductor. Consequently, the connection force between the second resilient conductor and outer conductor is smaller than that between the center conductor and the first resilient conductor. In a test, if the self-support cantilever portions (j1, k1) are placed at a transversely inclined angle rather than placed horizontally, a certain finger portion “k1” of the second resilient conductor may require higher bearing force. However, since the connection force between the second resilient conductor and the outer conductor is smaller than that between the center conductor and the first resilient conductor, the second resilient conductor may be easily damaged.

As shown in FIG. 6, a patent with patent number U.S. Pat. No. 5,853,295 discloses an angle connector “m” for changing a coaxial connector to a planar structure. The coaxial side terminal is configured to form a given angle of planar terminal. However, the connector is not a commercial product and is of high cost for application. Besides, unlike coaxial cable assembly, before making the planar side terminal trace, we cannot test the angle connector's electrical performance as easily as test a coaxial cable. Moreover, since the connector is structurally non-flexible, we cannot shape it easily as we did for a coaxial cable.

In order to overcome above shortcomings, inventor had the motive to study and develop the present invention.

### SUMMARY OF THE INVENTION

An object of the present invention is to provide a coaxial-cable probe structure, which is of low cost, has better continuity at interfaces, and is effective in reducing reflection noise and enhancing the mechanism strength.

In order to achieve above object, the present invention provides a coaxial-cable probe structure comprising a coaxial cable and a probing element. The coaxial cable is formed by filling and fixing an inner conductor into an outer conductor via a dielectric material. The dielectric material of the coaxial cable and the outer conductor are provided with a cutting surface. The inner conductor protrudes from the cutting surface and forms a terminal end. The coaxial cable is provided with a cutting part and the cutting part is provided with an oblique surface relative to the coaxial cable so as to expose the inner conductor, the dielectric material, and the outer conductor from the oblique surface. The oblique surface extends to the terminal end of the inner conductor. The probing element includes a first, a second, and a third probes and each probe has a front and a rear interfaces. The front interface of the second probe is connected with part of the inner conductor exposed from the oblique surface. Part of the inner conductor protruding from the cutting surface is electrically and mechanically connected with the second probe to form a cantilever structure. The front interfaces of the first and the third probes are electrically connected to the outer conductor of the coaxial cable. The rear interface of each probe is used to contact the bonding pad of an element under test.

In practice, the front interfaces of the first and the third probes are substantially connected with each other for being electrically connected with parts of the outer conductor of the coaxial cable that are adjacent to two lateral sides and the front side of the area of the coaxial cable corresponding to the front interface of the second probe. Besides, a space is formed between the first and the third probes for placing the second probe therein.

In practice, the part of the inner conductor exposed from the oblique surface is cut to form an elongate oval shape.

In practice, the front interfaces of the first, the second, and the third probes are designed in plane shape for being connected to the coaxial cable. The rear interfaces of the first, the second, and the third probes are designed in pointed shape for being in contact with the bonding pad of an element under test.

The following detailed description, given by way of examples or embodiments, will best be understood in conjunction with the accompanying drawings.

### BRIEF DESCRIPTION OF THE DRAWINGS

FIG. 1 is an exploded perspective view of an embodiment of a coaxial-cable probe structure of the present invention.

FIG. 2 is a schematic view showing the coaxial cable in the embodiment of the present invention.

FIG. 3 is a perspective view showing the embodiment of the coaxial-cable probe structure of the present invention.

FIG. 4 is a schematic view showing the structure disclosed by a patent with patent number U.S. Pat. No. 4,871,964 that belongs to prior art.

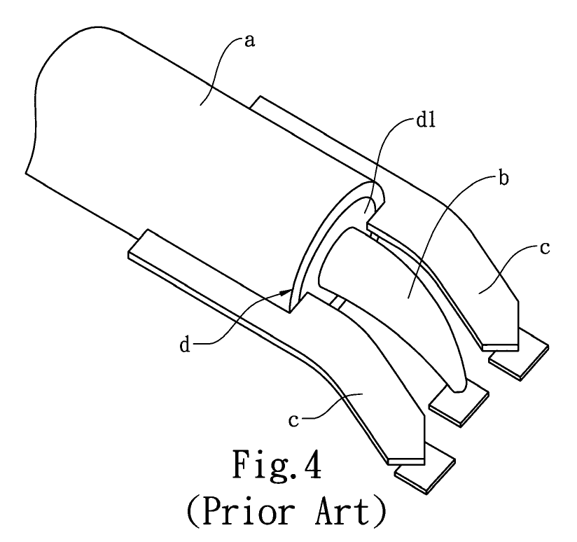

FIG. 5 is a schematic view showing the structure disclosed by a patent with patent number U.S. Pat. No. 5,506,515 that belongs to prior art.

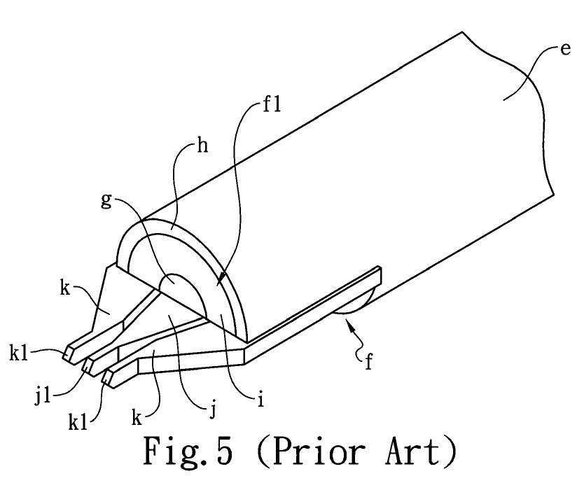

FIG. 6 is a schematic view showing the structure disclosed by a patent with patent number U.S. Pat. No. 5,853,295 that belongs to prior art.

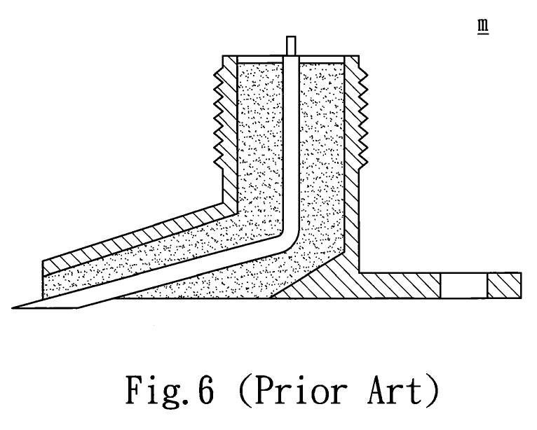

### DETAILED DESCRIPTION

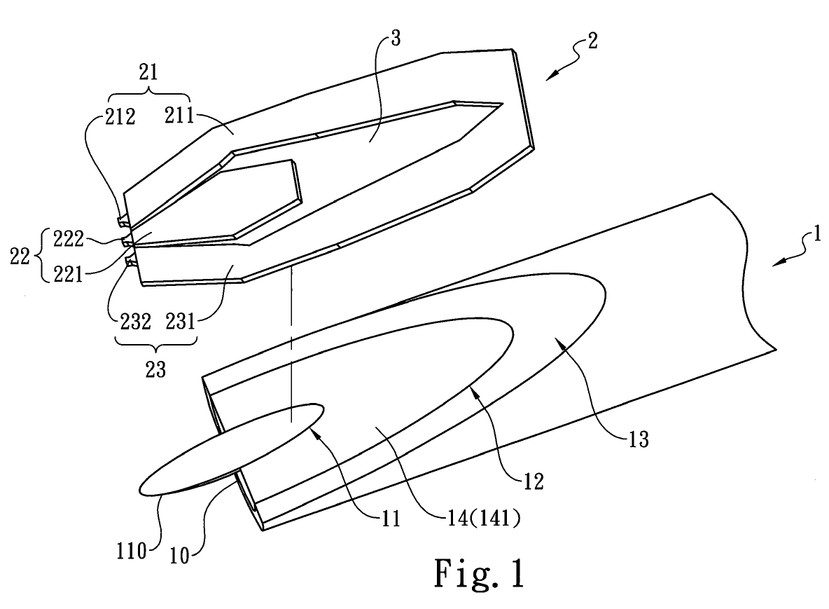

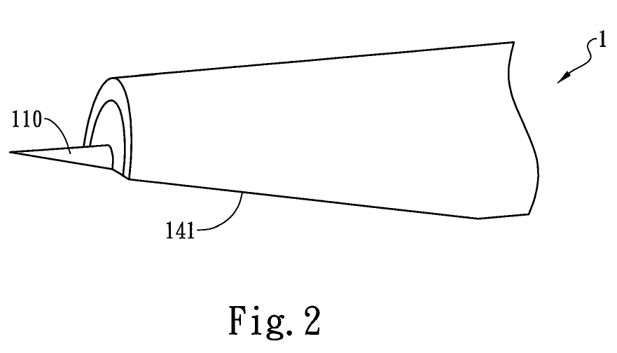

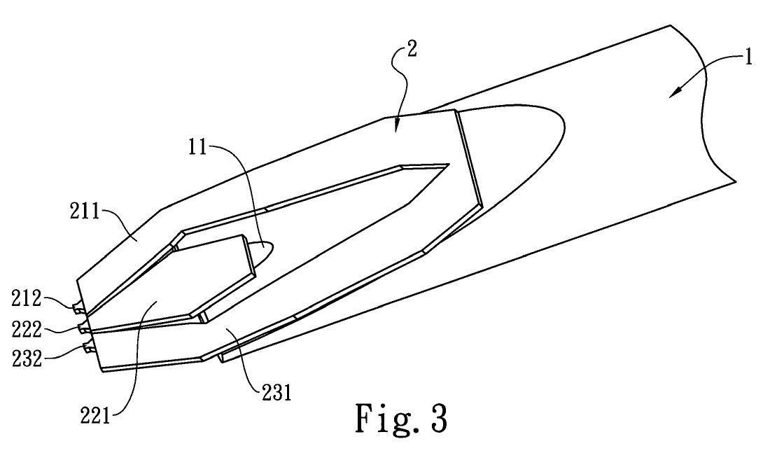

Please refer to FIGS. 1 to 3 showing an embodiment of a coaxial-cable probe structure of the present invention. The coaxial-cable probe structure comprises a coaxial cable 1 and a probing element 2.

Filling and fixing an inner conductor 11 into an outer conductor 13 via a dielectric material 12 forms the coaxial cable 1. The dielectric material 12 of the coaxial cable 1 and the outer conductor 13 are provided with a cutting surface 10. The inner conductor 11 protrudes from the cutting surface 10 and forms a terminal end 110. The coaxial cable 1 is provided with a cutting part 14 and the cutting part 14 is provided with an oblique surface 141 relative to the coaxial cable 1, so as to expose the inner conductor 11, the dielectric material 12, and the outer conductor 13 from the oblique surface 141. The oblique surface 141 extends to the terminal end 110 of the inner conductor 11. The inner conductor 11 is cut to form an elongate oval shape and to be flatly exposed from the oblique surface 141.

The probing element 2 includes a first, a second, and a third probes (21, 22, 23). Each probe has a front and a rear interfaces (211, 212, 221, 222, 231, 232). The front interfaces (211, 221, 231) of the first, second, and third probes (21, 22, 23) are designed in plane shape for being connected to the coaxial cable 1. The rear interfaces (212, 222, 232) of the first, second, and third probes (21, 22, 23) are designed in pointed shape for being in contact with the bonding pad of an element under test. The front interface 221 of the second probe 22 is electrically connected with part of the inner conductor 11 exposed from the oblique surface 141. Part of the inner conductor 11 protruding from the cutting surface 10 is electrically and mechanically connected with the second probe 22 to form a cantilever structure. The front interfaces (211, 231) of the first and third probes (21, 23) are electrically connected to the outer conductor 13 of the coaxial cable 1. In this embodiment, the front interfaces (211, 231) of the first and third probes (21, 23) are substantially connected with each other for being electrically connected with parts of the outer conductor of the coaxial cable that are adjacent to two lateral sides and the front side of the area of the coaxial cable corresponding to the front interface of the second probe. Besides, a space 3 is formed between the first and third probes (21, 23) for placing the second probe 22 therein.

Therefore, when in practice, after part of the coaxial cable 1 is cut to form a cutting part, the terminal end 110 of the inner conductor 11 of the coaxial cable 1 protrudes from the cutting surface 10. The terminal end 110 of the inner conductor 11 is cut to form an elongate oval shape and to be flatly exposed from the oblique surface 141. Moreover, because the front interfaces (211, 221, 231) of the first, second, and third probes (21, 22, 23) are designed in plane shape, the inner conductor 11 can be in full contact with the front interface 221 of the second probe 22. The front interfaces (211, 231) of the first and third probes (21, 23) are respectively connected with parts of the outer conductor of the coaxial cable that are adjacent to two lateral sides and the front side of the area of the coaxial cable corresponding to the front interface of the second probe.

Accordingly, the coaxial-cable probe structure of the present invention can be designed to be installed on the probe support element in a probe station and can be moved to suitable location. The rear interfaces (212, 222, 232) of the first, second, and third probes (21, 22, 23) are in contact with the bonding pad (an individual component) of an element (such as a wafer) under test.

A cutting part 14 is provided on the terminal end at which the coaxial cable 1 and the probing element 2 are connected with each other. The terminal end 110 of the inner conductor 11 is cut to protrude from the cutting surface 10. Part of the inner conductor 11 exposed from the oblique surface 141 is connected with the front interface 221 of the second probe 22. Therefore, based on above features, the damaged area of the inner conductor 11 in the coaxial cable can be reduced under the condition of the same length of cantilever. Consequently, the transmission loss and reflection noise can be reduced further. Moreover, a larger soldering point can be formed after the outer conductor 13 is connected with the front interfaces (211, 231) of the first and third probes (21, 23). Because the terminal end of the outer conductor 13 directly forms a continuous contact surface, the outer conductor 13 can be in better contact with the first and third probes (21, 23). Consequently, the boundary discontinuity can be decreased so as to improve the impedance match and effectively reduce the reflection noise.

As disclosed in the above description and attached drawings, the present invention can provide a coaxial-cable probe structure, which has simple structure and is effective in lowering the reflection noise. It is new and can be put into industrial use.

Although the embodiments of the present invention have been described in detail, many modifications and variations may be made by those skilled in the art from the teachings disclosed hereinabove. Therefore, it should be understood that any modification and variation equivalent to the spirit of the present invention be regarded to fall into the scope defined by the appended claims.

What is claimed is:

1. A coaxial-cable probe structure, comprising:
a coaxial cable, formed by filling and fixing an inner conductor into an outer conductor via a dielectric material, where the dielectric material of the coaxial cable and the outer conductor are provided with a cutting surface; the inner conductor protrudes from the cutting surface and forms a terminal end; the coaxial cable is provided with a cutting part and the cutting part is provided with an oblique surface relative to the coaxial cable, so as to have the inner conductor, the dielectric material, and the outer conductor exposed from the oblique surface; the oblique surface extends to the terminal end of the inner conductor; and
a probing element, including a first, a second, and a third probe and each probe having a front and a rear interface, where the front interface of the second probe is connected with part of the inner conductor exposed from the oblique surface; part of the inner conductor protruding from the cutting surface is electrically and mechanically connected with the second probe to form a cantilever structure; the front interfaces of the first and the third probes are electrically connected to the outer conductor of the coaxial cable; the rear interface of each probe is used to contact the bonding pad of an element under test.

2. The coaxial-cable probe structure as claimed in claim 1, wherein a space is formed between the first and the third probes for placing the second probe therein.

3. The coaxial-cable probe structure as claimed in claim 1, wherein part of the inner conductor exposed from the oblique surface is cut to form an elongate oval shape.

4. The coaxial-cable probe structure as claimed in claim 1, wherein the front interfaces of the first, the second, and the third probes are designed in plane shape for being connected to the coaxial cable while the rear interfaces of the first, the second, and the third probes are designed in pointed shape for being in contact with the bonding pad of an element under test.

5. The coaxial-cable probe structure as claimed in claim 1, wherein the front interfaces of the first and the third probes are substantially connected with each other for being electrically connected with parts of the outer conductor of the coaxial cable that are adjacent to two lateral sides and the front side of the area of the coaxial cable corresponding to the front interface of the second probe.

6. A coaxial-cable probe structure, comprising:
a coaxial cable, formed by filling and fixing an inner conductor into an outer conductor via a dielectric material, where the dielectric material of the coaxial cable and the outer conductor are provided with a cutting surface; the inner conductor protrudes from the cutting surface and forms a terminal end; the coaxial cable is provided with a cutting part and the cutting part is provided with an oblique surface relative to the coaxial cable, so as to have the inner conductor, the dielectric material, and the outer conductor exposed from the oblique surface; the oblique surface extends to the terminal end of the inner conductor; and
a probing element, including a first, a second, and a third probe and each probe having a front and a rear interface, where the front interfaces of the first and the third probes are substantially connected with each other for being electrically connected with parts of the outer conductor of the coaxial cable that are adjacent to two lateral sides and the front side of the area of the coaxial cable corresponding to the front interface of the second probe; the rear interface of each probe is used for being in contact with the bonding pad of an element under test.

7. The coaxial-cable probe structure as claimed in claim 6, wherein a space is formed between the first and the third probes for placing the second probe therein.

8. The coaxial-cable probe structure as claimed in claim 6, wherein part of the inner conductor exposed from the oblique surface is cut to form an elongate oval shape.

9. The coaxial-cable probe structure as claimed in claim 6, wherein the front interfaces of the first, the second, and the third probes are designed in plane shape for being connected to the coaxial cable while the rear interfaces of the first, the second, and the third probes are designed in pointed shape for being in contact with the bonding pad of an element under test.
